(19) United States
(12) Patent Application Publication
(10) Pub. No.: US 2026/0129795 A1
(43) Pub. Date: May 7, 2026

(54) TRAY SYSTEM FOR LIQUID COOLANT SYSTEMS FOR ELECTRONICS ASSEMBLIES

(71) Applicant: AMD Design, LLC, Wilmington, DE (US)

(72) Inventors: Paul Harold ANDERSON, Leander, TX (US); Sruti CHIGULLAPALLI, Seattle, WA (US)

(73) Assignee: AMD Design, LLC, Wilmington, DE (US)

(21) Appl. No.: 18/937,669

(22) Filed: Nov. 5, 2024

(51) Int. Cl. H05K 7/20

(52) U.S. Cl. CPC H05K 7/20272

(57) ABSTRACT

A tray system for capturing a liquid that leaks from a liquid connector assembly of a liquid coolant system for an electronic assembly, the tray system including: a tray section including a floor and one or more tray walls, the floor configured to extend underneath one or more components of the liquid connector assembly; and an engagement section coupled with the tray section and including one or more engagement portions configured to position the tray section beneath the one or more components of the liquid connector assembly to capture the liquid.

### FIELD

This disclosure is directed to a method and product to contain liquid coolant drips and spillage in electronics systems and assemblies having a liquid coolant system, for example, liquid cooled servers.

### BACKGROUND

Electronic components are often assembled together creating electronic equipment or assemblies, for example, servers. These electronic assemblies are often stacked and connected together in racks. These pluralities of electronic components forming electronic equipment and/or electronic assemblies, including electronic racks, often generate and dissipate heat. Heat is often detrimental to the performance of the electronic assemblies. Often these electronic assemblies, for example, electronic assembly racks, contain or integrate a cooling system, for example a liquid coolant system, for cooling the electronic equipment/assemblies and/or electronic racks. The liquid cooling system usually includes a supply of liquid coolant, for example, to a heat exchanger, and a return of the liquid coolant, for example, from the heat exchanger. Hoses incorporating liquid coolant (LC) assemblies, e.g., quick disconnect (QD) assemblies, are often used to form a conduit to route the liquid coolant in the liquid coolant system. A first component, e.g., referred to as a liquid connector (LC) fitting, of the liquid connector (LC) assembly is often fitted to a liquid connector (LC) manifold of the liquid coolant system of the electronics assembly (e.g., the chassis of the electronics assembly) while a second component, e.g., referred to as a liquid connector (LC) plug, of the LC assembly is often attached to a hose that forms a conduit for the liquid of the liquid coolant system to flow. The LC fitting is configured to attach to the LC plug in a leak resistant manner. A common LC assembly is a quick disconnect (QD) assembly having a LC fitting, referred to as a quick disconnect (QD) fitting that is often easily and quickly connected and disconnected from the LC plug, referred to as a quick disconnect (QD) plug, and typically in a self-locking manner.

While connecting and disconnecting the LC assemblies, liquid coolant can leak from the LC fitting and/or the LC plug. In addition, leaks from the LC assemblies can result from operation of the electronic assemblies, e.g., from vibrations, shock, thermal expansion, movement, shipment, and the like. Liquid coolant leaking from the LC assemblies can cause safety hazards and/or damage to the electronic assemblies. For example, liquid leaking from the LC assemblies (e.g., during connection and/or disconnection of the LC assemblies and/or during operation) can drip onto the electronic components and cause a short circuit and/or cause a fire. In addition, leaking liquid may cause a worker to slip, thereby causing injury and/or cause expensive secondary damage to cooling lines, cabling, etc. Different systems and techniques have been devised to reduce leaks from LC assemblies such as valves and other mechanisms. However, the problem of leaking LC assemblies and liquid leaking during connections of LC assemblies and disconnections of LC assemblies still persists. It would be beneficial and advantageous if a technique, system, and/or mechanism could be developed which would alleviate and/or eliminate the problems associated with liquid leaking from LC assemblies in liquid coolant systems.

### SUMMARY

One or more methods, systems, mechanisms, and/or products for containing a liquid that leaks or escapes from a liquid connector (LC) assembly (e.g., a QD assembly) in a liquid coolant system for an electronics assembly (e.g., a liquid cooled server) are described. In one or more implementations, the methods, systems, mechanisms, and/or products have application for containing a liquid coolant that escapes from a liquid connector (LC) assembly (e.g., a QD assembly) of a liquid coolant system for an electronics assembly (e.g., a liquid cooled server). In one or more implementations, the system, mechanism, and/or product takes the form of a tray system configured and arranged to attach to the liquid coolant system, a chassis of the electronics assembly, and/or a liquid connector (LC) manifold, e.g., a quick disconnect (QD) manifold, proximate the LC assembly. For example, the tray system may be configured to extend underneath at least a portion of the LC assembly.

A tray system is described. The tray system is configured to capture a liquid that leaks from a liquid connector assembly of a liquid coolant system for electronic assemblies. The tray system comprises a tray section including a floor and one or more tray walls. The floor is configured to extend underneath one or more components of the liquid connector assembly. The tray system also includes an engagement section coupled with the tray section. The engagement section has one or more engagement portions configured to position the tray section underneath the components of the liquid connector assembly to capture the liquid.

A method of capturing liquid that leaks from a liquid connector assembly of a liquid coolant system for an electronics assembly is also described. The method includes connecting a tray system to the liquid coolant system in proximity to the liquid connector assembly such that a tray section of the tray system having a floor and one or more tray walls is positioned beneath at least a portion of the liquid connector assembly. The method also includes performing at least one of installing or disconnecting a first component of the liquid connector assembly to or from a second component of the liquid connector assembly.

The foregoing summary is illustrative only and is not intended to be in any way limiting. In addition to the illustrative aspects, implementations, and features described above, further aspects, implementations, and features will become apparent by reference to the drawings and the following detailed description. In the drawings, like reference numbers indicate identical or functionally similar elements.

### BRIEF DESCRIPTION OF THE DRAWINGS

FIG. 1 illustrates a top perspective view of two liquid connector (LC) assemblies of a liquid cooled electronics assembly in a disconnected state showing liquid coolant dripping from LC fittings of the two LC assemblies.

FIG. 2 illustrates a top perspective view of two LC assemblies of a liquid cooled electronics assembly in a connected state with an example implementation of an installed tray system.

FIG. 3 illustrates a top perspective view two LC assemblies of a liquid cooled assembly with a first LC assembly in a connected state and a second LC assembly in a disconnected state with liquid coolant dripping from a LC fitting of the second LC assembly into the example implementation of the installed tray system of FIG. 2.

FIG. 4 illustrates a perspective view of the two connected LC assemblies with the example implementation of the installed tray system of FIG. 2.

FIG. 5 illustrates a side perspective view of two LC assemblies of a liquid cooled electronics assembly in a disconnected state with another example implementation of an installed tray system capturing liquid coolant leaking from two LC fittings of the two LC assemblies.

FIG. 6 illustrates a side perspective view of the two LC fittings and the installed tray system of FIG. 5 capturing leaking liquid coolant.

FIG. 7A illustrates a horizontal tray system of FIGS. 2-4.

FIG. 7B illustrates a vertical tray system of FIGS. 5 and 6.

FIG. 8 illustrates a top perspective view of the tray system of FIGS. 2-4 installed in an electronics assembly on a liquid connector (LC) manifold where two LC plugs are being connected/disconnected to the two LC fittings mounted on the LC manifold.

FIG. 9 illustrates a top perspective view of the tray system of FIG. 8 being removed from the liquid coolant system of an electronics assembly.

FIG. 10 illustrates the vertical tray system of FIGS. 5 and 6 configurable to mount on and attach to a LC manifold of a liquid coolant system of an electronics assembly, where the tray system receives a liquid absorbent sponge.

FIG. 11 illustrates a side perspective view of another implementation of a tray system installed in an electronics assembly to capture coolant liquid that potentially leaks from a single LC assembly.

FIG. 12 illustrates a side perspective view of another implementation of a tray system installed in an electronics assembly to capture coolant liquid that potentially leaks from multiple LC assemblies.

FIG. 13 illustrates a side perspective view of another implementation of a tray system installed in an electronics assembly to capture coolant liquid that potentially leaks from multiple LC assemblies.

### DETAILED DESCRIPTION

### Overview

Heat generated and released by electronic components and assemblies can decrease performance of the electronic components/assemblies and unduly decrease the lifespan of the electronic components/assemblies. To mitigate heat, electronic components and assemblies often include liquid coolant systems to transfer heat and/or carry heat away from the electronic components and assemblies. The liquid coolant systems contain a liquid coolant and often have a liquid connector (LC) assembly manifold having one or more liquid connector (LC) assemblies to connect hoses and/or conduits between different parts of the liquid coolant system. The hoses form conduits to permit the liquid coolant to flow to different parts of the electronic assemblies to dissipate heat, for example, to and from a heat exchanger.

The liquid coolant system and/or hoses often contain and/or use liquid connector (LC) assemblies to connect/disconnect the hose to/from the liquid coolant system. One form of liquid connector (LC) assemblies includes quick disconnect (QD) assemblies that permit easy and quick connection/disconnection of the hose to/from the liquid coolant system. The LC assemblies, e.g., the QD assemblies, are often self-locking. In an example, the LC assembly (e.g., QD assembly) includes a liquid connector (LC) fitting (e.g., a quick disconnect (QD) fitting) mounted to a liquid connector (LC) manifold (e.g., a quick disconnect (QD) manifold) of a liquid coolant system that connects to liquid connector (LC) plug (e.g., a quick disconnect (QD) plug). Operating these liquid connector (LC) assemblies (e.g., connecting and/or disconnecting or while the systems are in use) can sometimes result in some of the liquid coolant being released, which can cause damage to the electronic assemblies (e.g., the server). For example, the liquid coolant can drip onto a circuit board in the electronic assembly located underneath the liquid connector (LC) assemblies and cause a short circuit. The liquid coolant can also drip outside the chassis of the electronics assembly causing a hazard to workers or cause expensive damage to cooling lines, cabling, etc. It is desirable to overcome these problems of liquid coolant leaks and/or drips in the liquid coolant system of electronic assemblies as a result of leaks from, for example, vibration, shock, heat expansion, and/or from handling liquid connector (LC) assemblies, including connection and disconnection of hoses in electronics assemblies having liquid coolant systems, e.g., liquid cooled servers.

Described herein is a system, mechanism, product and/or method for capturing liquid that leaks from a liquid connector assembly of a liquid cooling system for electronic assemblies. In one or more implementations, the system includes a tray section and an engagement section. The tray section includes a floor and one or more tray walls, where the floor has a length, a width, and a perimeter, and each tray wall has a length and a height. In an example configuration, the one or more tray walls extend from the floor proximate the perimeter of the floor, and the floor and one or more tray walls form an opening to receive, and a chamber to capture and/or contain, liquid that leaks from one or more components of a liquid connector assembly. The engagement section includes one or more engagement portions adapted and configured to position the tray section beneath one or more components of the liquid connector assembly to capture the leaked liquid. In an aspect, the one or more engagement portions are configured to fit and attach to one or more of the electronics assemblies, the liquid cooling system, or a manifold (e.g., a liquid connector manifold for the liquid coolant system). In one or more aspects at least the engagement section is configured to frictionally engage the liquid coolant system, and in a further aspect at least the engagement section is configured to snap fit and attach to the liquid coolant system.

In an implementation, the liquid coolant system has a liquid connector manifold and at least one component of the liquid connector assembly is for attaching to the liquid connector manifold, wherein the engagement section is configured to fit and attach to the liquid connector manifold. In a further implementation, the one or more engagement portions form at least a partial opening to fit around the liquid connector manifold, and in a configuration the at least partial opening formed by the one or more engagement portions substantially surrounds the liquid connector manifold. The length of the floor in an arrangement is configured and sized to extend a length of the at least one component of the liquid connector assembly for attaching to the liquid connector manifold, and the height of the tray walls are at least 5 mm or more.

In a further aspect, at least a portion of the engagement section is flexible to stretch, fit over, and attach to a portion of the liquid cooling system. At least a portion of the engagement section, preferably the one or more engagement portions, is formed of a flexible material group, wherein the flexible material group consists of at least one of: silicone, rubber, neoprene, ethylene propylene diene monomer (EPDM), and combinations thereof. The tray section and the engagement section in an implementation are formed by injection molding, and in a further implementation the tray section is integrally formed with and of the same material as the engagement section. The system in one or more implementations further includes a sponge received and held by the chamber. In one or more implementations, the one or more engagement portions include one or more engagement walls each having a height between about 5 mm and 15 mm and having a length between about 20 mm and 100 mm.

A method of capturing liquid from a liquid connector assembly of a liquid coolant system for an electronics assembly is also disclosed and discussed. The method in one or more implementations includes: connecting a tray system to the liquid coolant system in proximity to the liquid connector assembly wherein a tray section having a floor and one or more tray walls configured for capturing the liquid is positioned beneath the liquid connector assembly; and performing at least one of installing or disconnecting a first of the liquid connector assembly components from a second of the liquid connector assembly components. Connecting the tray system to the liquid coolant system includes fitting and attaching an engagement section of the tray system to a portion of the liquid coolant system, and in a preferred method includes frictionally fitting the engagement section to a liquid connector manifold of the liquid coolant system. The method can optionally include stretching an opening of the engagement section, for example an opening formed by one or more engagement walls, over the liquid connector manifold of the liquid coolant system. A replaceable sponge adapted to absorb liquid can be positioned/disposed within or on the tray section of the tray system, and the method can in an implementation further include removing the replaceable sponge from the tray section of the tray system. The method can further include removing the tray system by for example disconnecting the first of the liquid connector assembly components from the second of the liquid connector assembly components; and disconnecting and removing the tray system from the liquid cooling system.

In the following description, numerous specific details are set forth, such as particular structures, components, materials, dimensions, processing steps and techniques, in order to provide an understanding of the various implementations of the present application. However, it will be appreciated by one of ordinary skill in the art that the various implementations of the present application may be practiced without these specific details. In other instances, well-known structures or processing steps have not been described in detail in order to avoid obscuring the present application.

### Example Environment

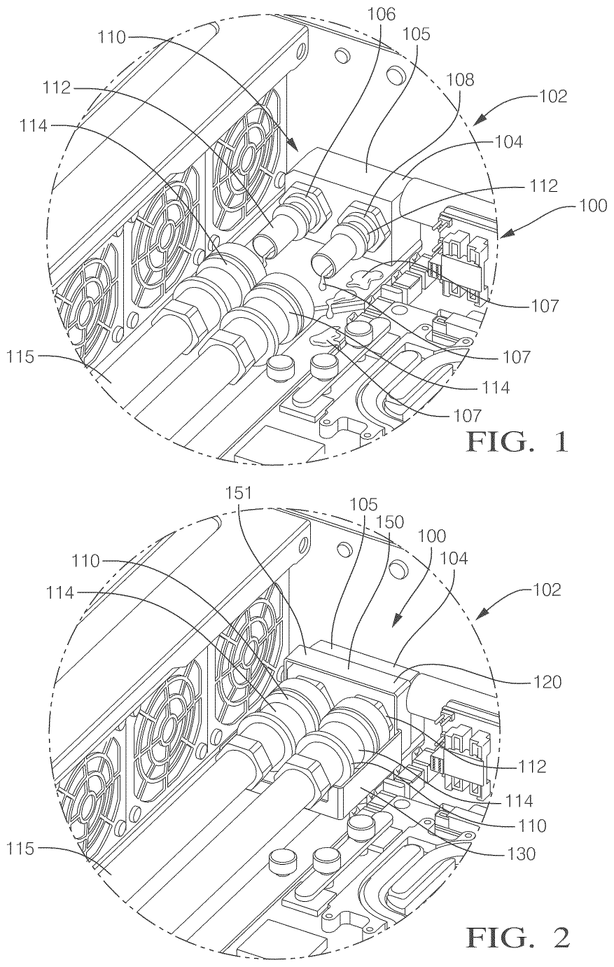

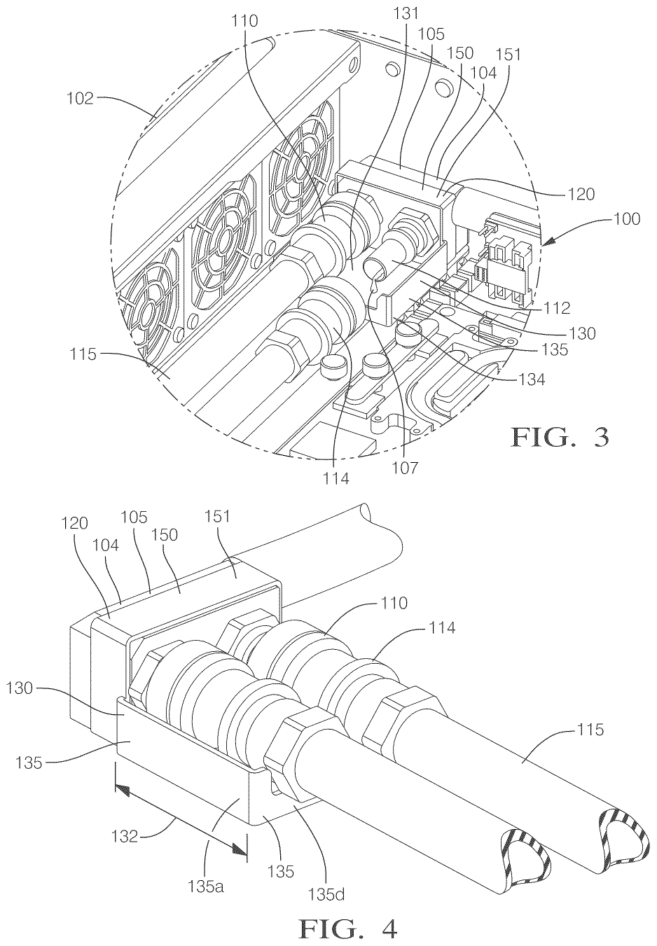

FIGS. 1-5 illustrate an example environment for a tray system 120 to capture liquid coolant 107 that leaks from one or more LC assemblies 110 of a liquid coolant system 104 in an electronics assembly 100, for example, as an electronics rack 102. The LC assembly 110 (e.g., QD assembly) in an example implementation includes an LC fitting 112 (e.g., QD fitting), also referred to as a first component of liquid connector (LC) assembly, connectable to an LC plug 114 (e.g., QD connector), also referred to as a second component of the liquid connector (LC) assembly. The LC fitting 112 is usually configured as an insert received in a receptacle formed by the LC plug 114, but other configurations for LC fitting 112 and LC plug 114 are contemplated. The liquid coolant system 104 generally includes a supply side 106 of liquid coolant 107 and a return side 108 of liquid coolant 107. The liquid coolant system 104 usually includes a manifold 105 (e.g., liquid manifold, LC manifold, QD manifold) to which LC fitting 112 (QD fitting) is mounted, wherein the LC fitting 112 generally extends from the manifold 105 a distance D (see FIG. 6). A hose 115 forming a conduit to route the liquid coolant 107 in the liquid coolant system 104 usually includes LC plug 114 that is connectable to LC fitting 112 mounted to manifold 105.

### Example Implementation

FIGS. 4 and 7A illustrate an example implementation of a tray system 120 that is horizontally oriented to capture liquid coolant 107 that might leak from one or more LC assemblies 110 in a liquid coolant system 104 of an electronics assembly 100. FIGS. 6 and 7B illustrate an example implementation of a tray system 120 that is vertically oriented to capture liquid coolant 107 that might leak from one or more LC assemblies 110 in a liquid coolant system 104 of an electronics assembly 100.

Tray system 120 includes a tray section 130 and an engagement section 150. Tray section 130 is configured to capture liquid coolant 107 leaking from LC assembly 110 and/or one or more components of LC assembly 110, for example, LC fitting 112 and/or LC plug 114. Engagement section 150 is configured for attaching, or coupling, tray system 120 to one or more of the liquid coolant system 104 or the electronics assembly 100, for example, the chassis of the electronics assembly 100 (e.g., the electronics rack 102).

Tray section 130 includes a floor 131 and one or more tray walls 135 for capturing and retaining the liquid coolant 107 that might leak from the liquid coolant system 104. Floor 131 is generally rectangular in shape and has a length 132, a width 133, and a perimeter 134. While floor 131 is described as being generally rectangular it can be appreciated that the shape of floor 131 is not limited to a rectangle and may take many different forms including square, oval, round, polygonal, and/or other shapes. The floor 131 in one or more implementations has a length 132 of about 25 mm to 100 mm and a width 133 between 20 mm and 60 mm. Other dimensions for length 132 and width 133 are contemplated. As can be appreciated, the length 132 is roughly the same size as the distance D that the component of the LC assembly 110 (typically the LC fitting 112 or LC plug 114) that mounts to the manifold 105 (or liquid coolant system 104 or electronics assembly chassis) and extends from the manifold 105 (or liquid coolant system 104 or electronics assembly chassis), and preferably is roughly the same size as distance D or slightly greater. Generally, the floor 131 is sized so that it is large enough to receive and capture liquid coolant 107 as it drips from the LC assembly 110. In addition, while floor 131 is generally flat, it can also be curved, angular, pyramidal, as well as other shapes.

Tray section 130 also includes one or more tray walls 135 extending from and proximate to the perimeter 134 of floor 131. That is, one or more tray walls 135 extend in a different direction than the floor 131 proximate to and preferably at the perimeter 134 of floor 131. Preferably, the one or more tray walls 135 extend perpendicular to the floor 131, although different angular directions are contemplated. For example, the one or more tray walls 135 can extend 45 degrees from the perimeter 134 of floor 131. Each tray wall 135 has a height 136 and a length 137, where the height 136 is typically between 5 mm and 20 mm, more preferably, between 12 mm and 15 mm. Each tray wall 135 typically has a length 137 that corresponds to the length 132 and/or the width 133.

The combination of floor 131 and one or more tray walls 135 are configured and/or shaped to capture and retain a quantity and/or volume of liquid. In this regard, the floor 131 and one or more tray walls 135 form a chamber 142 for capturing and retaining the liquid coolant 107 and has an opening 140 to chamber 142 located above the floor 131 to receive the liquid coolant 107. That is, the tray section 130 is open to receive the liquid coolant 107. The tray walls 135 are attached to, preferably integrally formed with, the floor 131 to form a container to hold and retain any liquid coolant 107 that might leak from LC assemblies 110 and/or liquid coolant system 104. The tray walls 135 and floor 131 are preferably configured to make removing the leaked liquid coolant from the tray section 130 easy. For example, one or more of the tray walls 135 can be curved and/or where the one or more tray walls 135 meet up with and join the floor 131 can have a radius of curvature or a fillet at the juncture where the floor 131 and one or more tray walls join.

In one or more implementations, tray section 130 is formed of a material that is resistant to the liquid coolant 107, and, in an implementation, is formed of a material resistant to Propylene glycol (PD), preferably PG25. In a preferred implementation, tray section 130 is formed from silicone, rubber, neoprene, and/or ethylene propylene diene monomer (EPDM). Other materials for forming tray section 130 are contemplated.

In the example implementations of FIGS. 4, 6, 7A and 7B, there are four tray walls 135, namely first tray wall 135a, second tray wall 135b, third tray wall 135c, and fourth tray wall 135d. First tray wall 135a is opposite third tray wall 135c and each of first and third tray walls 135a, 135c have a length 137 corresponding to length 132. Second tray wall 135b is opposite fourth tray wall 135d and each of second and fourth tray walls 135b, 135d have a length 137 corresponding to the width 133. It can be appreciated that one or more of tray walls 135 (e.g., tray walls 135a, 135b, 135c, and/or 135d) may contain one or more cut-outs 145 to accommodate the LC assemblies 110 and/or other features of the liquid coolant system 104 and/or electronics assemblies 100. For example, FIGS. 7A and 7B show cut-outs 145 in fourth tray wall 135d.

Engagement section 150 includes engagement portions 151 to engage, contact, and/or attach to electronics assembly 100, liquid coolant system 104, and/or the manifold 105. The engagement section 150, including engagement portions 151, in one or more arrangements preferably are sized and configured to fit over and attach to the liquid coolant system 104, more preferably sized and configured to fit over and attach to manifold 105 of liquid coolant system 104. The engagement section 150 and/or engagement portions 151 preferably are configured to frictionally engage the electronics assembly 100, liquid coolant system 104, and/or the manifold 105, and, in an implementation, the engagement section 150 and/or the engagement portions 151 are made of stretchable material and/or or configured to stretch to fit over and then contract onto electronics assembly 100, liquid coolant system 104, and/or the manifold 105. In one or more implementations, engagement section 150 and at least a portion of engagement portions 151 are formed from silicone, rubber, neoprene, and/or ethylene propylene diene monomer (EPDM). Other materials for forming engagement section 150 and/or at least a portion of engagement portions 151 are contemplated.

The engagement section 150 and/or the one or more engagement portions 151 preferably are installable on, and removeable from, electronics assembly 100, liquid coolant system 104, and/or the manifold 105. In one or more implementations the engagement section 150 and/or the one or more engagement portions 151 are snap fit onto the electronics assembly 100, liquid coolant system 104, and/or the manifold 105. In one or more configurations, the engagement section 150 and/or the engagement portions 151 form at least a partial opening (e.g., opening 152) to at least partially fit around the electronics assembly 100, liquid coolant system 104, and/or the manifold 105. In one or more aspects, opening 152 formed by the engagement section 150 and/or the one or more engagement portions 151 substantially surrounds the electronics assembly 100, liquid coolant system 104, and/or the manifold 105, and, in a further aspect, opening 152 formed by the engagement section 150 and/or the one or more engagement portions 151 entirely surrounds the electronics assembly 100, liquid coolant system 104, and/or the manifold 105 to form an enclosed space as shown in FIGS. 7A and 7B. In one or more implementations, opening 152 formed by engagement section 150 and the one or more engagement portions 151 is rectangularly shaped, although other shapes for opening 152 are contemplated.

The engagement section 150 is preferably attached to, or coupled with, tray section 130, more preferably integrally attached to tray section 130. The engagement section 150 is attached to the tray section 130 to position the tray section below the LC assembly 110, e.g., position the tray below the LC fitting 112. IN one or more implementations the tray section is configured to extend from the engagement section and to position the tray section in proximity to and just below the LC assembly 110, e.g., the LC fitting 112. For example, the engagement section 150 and/or the one or more engagement portions are configured to connect and/or attach to the electronics assembly, the liquid coolant system 104 and/or the manifold 105 in a manner so that the tray section (e.g., the floor 131) is about 5 mm or more, more preferably 10 mm-20 mm, beneath the electronics assembly, the liquid coolant system 104 and/or the manifold 105.

In one or more implementations, the engagement section 150 and/or the one or more engagement portions 151 are injection molded preferably injection molded as an integral single structure or piece. In a further arrangement, tray section 130 is injection molded, more preferably injection molded as an integral single piece, and more preferably injection molded with the engagement section 150 and/or the one or more engagement portions 151 as an integral single piece. In one or more configurations, the engagement section 150, the one or more engagement portions 151, and/or tray section 130 is made from a material that is resistant to the liquid coolant 107, preferably resistant to Propylene Glycol (PG), including PG25. In one or more implementations, engagement section 150, at least a portion of engagement portions 151, and tray section 130 are formed from silicone, rubber, neoprene, and/or ethylene propylene diene monomer (EPDM). Other materials for forming engagement section 150, at least a portion of engagement portions 151, and tray section 130 are contemplated.

In one or more implementations, one or more engagement portions 151 include engagement walls 155, where each engagement wall 155 has a length 156 and a width 157. Engagement walls 155 form opening 152 in engagement section 150. In the example implementations of FIGS. 4, 6, 7A and 7B, there are four engagement walls 155, namely first engagement wall 155a, second engagement wall 155b, third engagement wall 155c, and fourth engagement wall 155d. First engagement wall 155a is opposite third engagement wall 155c and each of first and third engagement walls 155a, 155c have a length 156 corresponding to a length of manifold 105 (or other attachment feature of liquid coolant system 104 and/or electronic assembly chassis to which engagement section 150 attaches). Second engagement wall 155b is opposite fourth engagement wall 155d and each of second and fourth engagement walls 155b, 155d have a length 137 corresponding to a width of manifold 105 (or other attachment feature of liquid coolant system 104 and/or electronic assembly chassis to which engagement section 150 attaches). It can be appreciated that engagement walls 155 (e.g., engagement walls 155a, 155b, 155c, and/or 155d) completely surround and form opening 152. The opening 152 may be any shape (e.g., round or rectangular) and be configured to attach to liquid coolant system 104, electronics assembly 100 (including electronics rack 102), and/or manifold 105.

Engagement walls 155 also each have a width 157, where the width 157 of engagement walls 155 are configured to provide enough surface area so engagement walls 155 frictionally engage and remain attached to the electronics assembly 100, liquid coolant system 104, and/or the manifold 105 during operation and shipment of the electronics assembly 100. In an example arrangement, engagement walls 155 are stretchable to fit over and contract onto manifold 105.

### Example Installation and Use

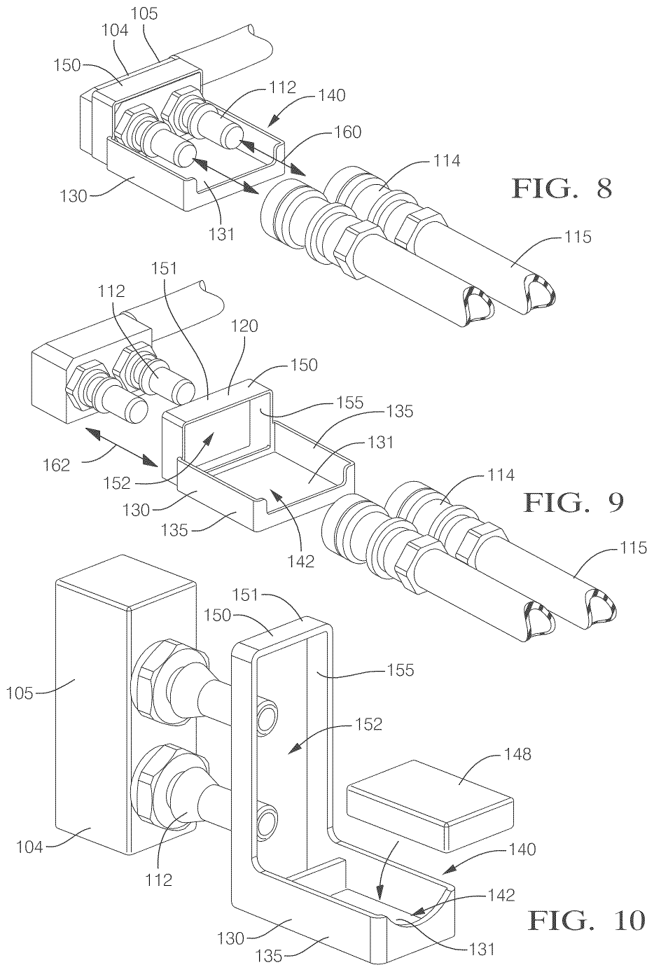

FIGS. 8 and 9 illustrate examples of installing and removing tray system 120 from a liquid coolant system 104 for an electronics assembly 100, more particularly, from a manifold 105 of the liquid coolant system 104. As shown in FIG. 8, tray system 120 is installed by connecting tray system 120 onto liquid coolant system 104, more particularly, manifold 105 by fitting engagement section 150 on liquid coolant system 104, more specifically, onto manifold 105. In an aspect, engagement section 150 frictionally engages liquid coolant system 104, more specifically, for example, frictionally engages manifold 105. In an arrangement, at least one of engagement section 150 or engagement portions 151, e.g., one or more of engagement walls 155a, 155b, 155c, 155d, is flexible and is stretched to fit over liquid coolant system 104, more specifically, stretched to fit over and contract onto manifold 105.

In an example implementation, tray system 120 is connected to liquid coolant system 104 in proximity to a LC assembly 110, preferably LC fitting 112, whereby the tray section 130 is positioned beneath the LC assembly 110, preferably underneath the LC fitting 112. In a further approach, the tray system 120 is connected to the liquid coolant system 104, e.g., to manifold 105, prior to installation or attachment of the LC plug 114 of the LC assembly 110 (e.g., the hose 115) to the LC fitting 112. After the tray system 120 is connected to the liquid coolant system 104, e.g., to the manifold 105, the LC plug 114 is attached to the LC fitting 112, e.g., to connect hose 115 to the liquid coolant system 104. FIG. 8 illustrates the disconnection and connection of two LC plugs 114 to two LC fittings 112 by arrows 160.

In an example arrangement and use, the LC plug 14 can be disconnected from the LC fitting 112 and tray system 120 can be removed from the liquid coolant system 104, e.g., from the manifold 105, as illustrated by arrow 162 in FIG. 9. The tray system 120 can be removed to replace with a new instance of tray system 120 and/or to remove any liquid coolant 107 that has collected in the tray system 120. The ability to remove tray system 120 from the electronics assembly 100, the liquid coolant system 104, and/or the manifold 105 permits easy service of the tray system 120 and removal of any liquid coolant 107 collected in the tray section 130 of the tray system 120 (e.g., removal and replacement of sponge 148).

### Further Implementations

FIG. 10 illustrates a perspective view of tray system 120 where tray section 130 is configured and adapted to receive and contain a sponge 148 for capturing and containing any liquid that leaks into chamber 142 of tray section 130. The sponge 148 captures the liquid and resists and/or prevents leaking liquid coolant 107 from contacting the circuitry in the electronics assembly and/or escaping outside the electronics assembly and/or onto other equipment where the electronics assembly 100 is located. The sponge 148 can be formed of any material that can absorb the liquid coolant used in the liquid coolant system, for example, sodium polyacrylate, collagen, etc. For example, the sponge 148, on contact with the liquid coolant, can convert to a gel. The sponge 148 may be easily removed from the tray system 120, e.g., tray section 130, and replaced. In addition, the tray system 120 can be easily removed and the sponge 148 thereafter removed and replaced.

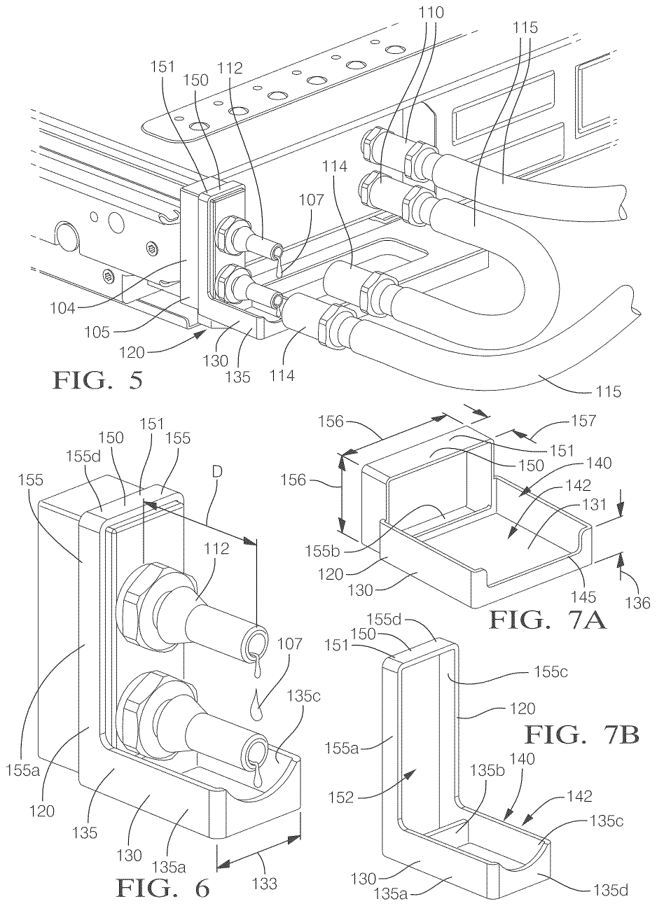

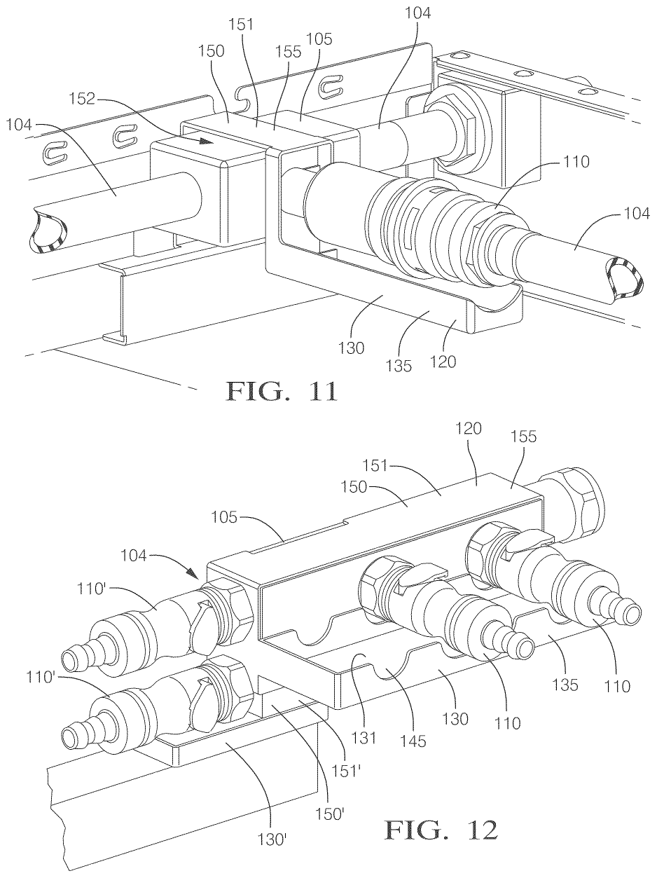

Tray system 120 can be sized and configured to accommodate and work with a plurality of different sized and configured LC assemblies, liquid coolant systems 104, and/or manifolds 105. For example, tray system 120 can be sized for double LC assemblies (e.g., manifolds configured for double LC assemblies), for example, double width LC assemblies as shown in FIGS. 2-4 and 7A and double-stacked vertical LC assemblies as shown in FIGS. 5-6 and 7B. Tray system 120 can also be configured for single LC assemblies (e.g., manifolds configured for single LC assembly), for example, as shown in FIG. 11. More specifically, tray system 120 can be sized and configured for an internal tee-shaped manifold that distributes liquid coolant to multiple points within an electronics assembly (e.g., server), as shown in FIG. 11, where engagement portions 151 of engagement section 150 fit over and onto manifold 105. In the implementation of FIG. 11, the engagement portions 151 form opening 152 to fit over and engage manifold 105, preferably frictionally engage manifold 105, and, optionally, in an engagement, snap fit onto manifold 105. It can be appreciated that, rather than engagement portions 151 fitting over the manifold 105, the engagement portions 151 can also fit under and frictionally engage the underside of the manifold 105. For example, engagement walls 155 can form opening 152 to fit on the underside of the manifold 105.

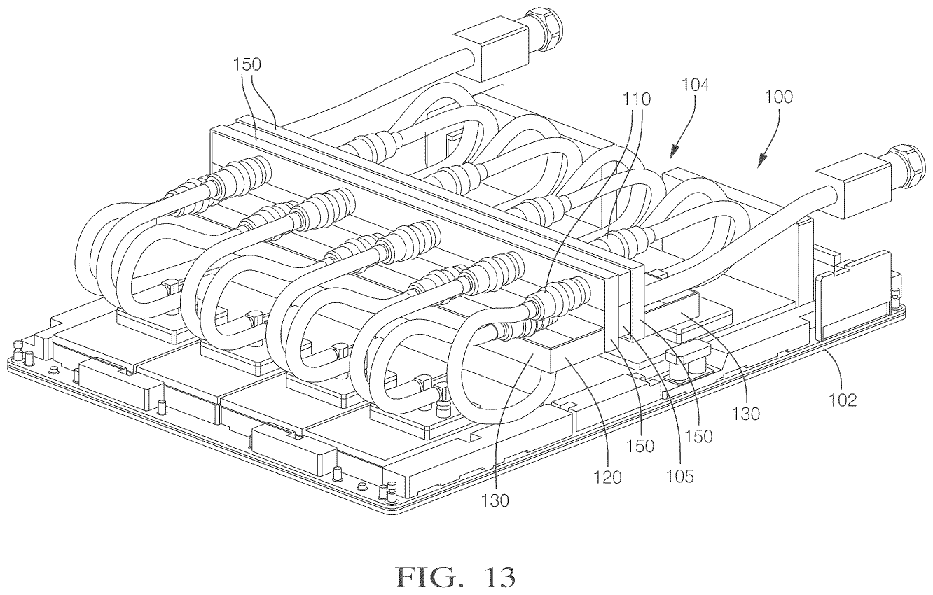

Tray system 120 can also be sized and configured for multiple LC assembly coverage such as shown in FIG. 12 where multiple tray sections 130, 130′ and multiple engagement sections 150, 150′ are provided to retain tray system 120 in position and locate the multiple tray sections 130, 130′ under respective LC assemblies 110 (e.g., LC assembly 110 and LC assembly 110′). For example, engagement portions 151 of engagement section 150 engage a first portion of manifold 105 to locate and position tray section 130 under multiple LC assemblies 110 that are oriented side by side to capture any liquid coolant 107 in chamber 142 and engagement portions 151′ of engagement section 150′ engage a second portion of manifold 105 to locate and position tray section 130′ under multiple LC assemblies 110 that are oriented vertically (e.g., LC assembly 110 and LC assembly 110′). FIG. 13 shows two tray systems 120 that are consolidated and sized and configured for multiple LC assembly coverage where the engagement section 150 is large and locates and positions tray section 130 underneath multiple (e.g., five) vertically oriented offset LC assemblies 110. It can be appreciated that tray section 130 of FIG. 13 (and tray section 130 in FIGS. 7A and 12) can include one or more partition walls (not shown) that can divide chamber 142 into multiple chambers 142a, 142b, 142c, . . . 142n. It can be appreciated that the partition walls can be formed similar to tray walls 135 but are not limited to being proximate of or at the perimeter 134 of floor 131 of tray section 130.

### EXAMPLES

A tray system configured to capture a liquid that leaks from a liquid connector assembly of a liquid coolant system for electronic assemblies, the tray system comprising: a tray section including a floor and one or more tray walls, the floor being configured to extend underneath one or more components of the liquid connector assembly; and an engagement section coupled with the tray section and including one or more engagement portions configured to position the tray section underneath the components of the liquid connector assembly to capture the liquid.

The tray system according to example 1, wherein the one or more engagement portions are configured to frictionally engage a portion of the liquid coolant system.

The tray system according to example 1 or 2, wherein the one or more engagement portions are configured to snap fit engage a portion of the liquid coolant system.

The tray system according to example 1, wherein: the liquid coolant system includes a liquid connector manifold; and the one or more engagement portions are configured to engage the liquid connector manifold.

The tray system according to example 4, wherein the one or more engagement portions form at least a partial opening configured to fit around the liquid connector manifold.

The tray system according to example 5, wherein the at least partial opening formed by the one or more engagement portions is configured to substantially surround the liquid connector manifold.

The tray system according to example 1, wherein: the floor is configured to extend at least a length of a coupling portion of the one or more components of the liquid connector assembly; and a height of the tray walls is at least 5 mm.

The tray system according to example 1, wherein the engagement portions are configured to stretch to fit over a portion of the liquid cooling system.

The tray system according to at least example 7, wherein the engagement portions are formed of at least one of: silicone, rubber, neoprene, or ethylene propylene diene monomer (EPDM).

The tray system according to example 1, wherein the tray section and the engagement section are formed by injection molding.

The tray system according to example 10, wherein the tray section and the engagement section are portions of a single structure.

The tray system according to example 1, further comprising a sponge disposed on the floor.

The tray system according to example 1, wherein the engagement portions include one or more engagement walls each having a height between 5 mm and 15 mm and having a length between 20 mm and 100 mm.

A method of capturing liquid that leaks from a liquid connector assembly of a liquid coolant system for an electronics assembly, the method comprising: connecting a tray system to the liquid coolant system in proximity to the liquid connector assembly such that a tray section of the tray system having a floor and one or more tray walls is positioned to extend underneath one or more components of the liquid connector assembly; and performing at least one of installing or disconnecting a first component of the liquid connector assembly to or from a second component of the liquid connector assembly.

The method of example 14, wherein connecting the tray system to the liquid coolant system includes attaching an engagement section of the tray system to a portion of the liquid coolant system.

The method of example 15, wherein attaching the engagement section includes frictionally fitting the engagement section to a liquid connector manifold of the liquid coolant system.

The method of example 16, wherein frictionally fitting the engagement section includes stretching an opening of the engagement section over the liquid connector manifold of the liquid coolant system.

The method of example 14, wherein the method includes positioning a replaceable sponge adapted to absorb liquid within the tray section of the tray system.

The method of example 14, wherein the method includes: disconnecting the first component from the second component; and disconnecting the tray system from the liquid cooling system.

A system comprising: a liquid manifold configured to be implemented in a liquid coolant system for electronic assemblies; a tray system configured to capture a liquid that leaks from a liquid connector assembly coupled with the liquid manifold, the tray system comprising: a tray section including a floor and one or more tray walls, the floor configured to extend underneath at least a portion of the liquid connector assembly; and an engagement section coupled with the tray section and including one or more engagement portions configured to attach to the liquid manifold and position the tray section underneath the at least portion of the liquid connector assembly to capture the liquid.

### Conclusion

The terminology used herein is for the purpose of describing particular implementations only and is not intended to be limiting of this disclosure. As used herein, the singular forms “a”, “an” and “the” are intended to include the plural forms as well, unless the context clearly indicates otherwise. It will be further understood that the terms “includes,” “comprises” and/or “comprising,” when used in this specification, specify the presence of stated features, integers, steps, operations, elements, components, subsystems, mechanisms, and/or groups but do not preclude the presence or addition of one or more other features, integers, steps, operations, elements, components, subsystems, mechanisms, and/or groups thereof. Further, the terms up, upper, down, lower, above, below, left, right, forward, rearward, first, second, third, and the like are intended to be understood in the context of the representations described and illustrated above so that a system, device, product, subsystem, and/or component may have such an orientation in reference to the frame or to various elements as supported by the frame or as illustrated in the drawing or figures.

The corresponding structures, materials, acts, and equivalents of all means or step plus function elements, if any, in the claims below are intended to include any structure, material, or act for performing the function in combination with other claimed elements as specifically claimed. The description of the present disclosure has been presented for purposes of illustration and description but is not intended to be exhaustive or limited to this disclosure in the form disclosed. Many modifications and variations will be apparent to those of ordinary skill in the art without departing from the scope and spirit of this disclosure. The various implementations were chosen and described in order to best explain the principles of this disclosure and the practical application, and to enable others of ordinary skill in the art to understand this disclosure for various implementations with various modifications as are suited to the particular use contemplated.

What is claimed is:

1. A tray system for capturing a liquid that leaks from a liquid connector assembly of a liquid coolant system for an electronic assembly, the tray system comprising:
a tray section including a floor and one or more tray walls, the floor being configured to extend underneath one or more components of the liquid connector assembly; and
an engagement section coupled with the tray section and including one or more engagement portions configured to position the tray section underneath the one or more components of the liquid connector assembly to capture the liquid.

2. The tray system according to claim 1, wherein the one or more engagement portions are configured to frictionally engage a portion of the liquid coolant system.

3. The tray system according to claim 1, wherein the one or more engagement portions are configured to snap fit engage a portion of the liquid coolant system.

4. The tray system according to claim 1, wherein:
the liquid coolant system includes a liquid connector manifold; and
the one or more engagement portions are configured to engage the liquid connector manifold.

5. The tray system according to claim 4, wherein the one or more engagement portions form at least a partial opening configured to fit around the liquid connector manifold.

6. The tray system according to claim 5, wherein the partial opening formed by the one or more engagement portions is configured to substantially surround the liquid connector manifold.

7. The tray system according to claim 1, wherein:
the floor of the tray section is configured to extend at least a length of a coupling portion of the one or more components of the liquid connector assembly; and
a height of the tray walls is at least 5 mm.

8. The tray system according to claim 1, wherein the one or more engagement portions are configured to stretch to fit over a portion of the liquid coolant system.

9. The tray system according to at least claim 7, wherein the one or more engagement portions are formed of at least one of: silicone, rubber, neoprene, or ethylene propylene diene monomer (EPDM).

10. The tray system according to claim 1, wherein the tray section and the engagement section are formed by injection molding.

11. The tray system according to claim 10, wherein the tray section and the engagement section are portions of a single structure.

12. The tray system according to claim 1, further comprising a sponge disposed on the floor of the tray section.

13. The tray system according to claim 1, wherein the one or more engagement portions include one or more engagement walls each having a height between 5 mm and 15 mm and having a length between 20 mm and 100 mm.

14. A method of capturing liquid that leaks from a liquid connector assembly of a liquid coolant system for an electronics assembly, the method comprising:
connecting a tray system to the liquid coolant system in proximity to the liquid connector assembly such that a tray section of the tray system having a floor and one or more tray walls is positioned to extend underneath one or more components of the liquid connector assembly; and
performing at least one of installing or disconnecting a first component of the liquid connector assembly to or from a second component of the liquid connector assembly.

15. The method of claim 14, wherein connecting the tray system to the liquid coolant system includes attaching an engagement section of the tray system to a portion of the liquid coolant system.

16. The method of claim 15, wherein attaching the engagement section includes frictionally fitting the engagement section to a liquid connector manifold of the liquid coolant system.

17. The method of claim 16, wherein frictionally fitting the engagement section includes stretching an opening of the engagement section over the liquid connector manifold of the liquid coolant system.

18. The method of claim 14, wherein the method includes positioning a replaceable sponge adapted to absorb liquid within the tray section of the tray system.

19. The method of claim 14, wherein the method includes:
disconnecting the first component from the second component; and
disconnecting the tray system from the liquid cooling system.

20. A system comprising:
a liquid manifold configured to be implemented in a liquid coolant system for an electronic assembly; and
a tray system for capturing a liquid that leaks from a liquid connector assembly coupled with the liquid manifold, the tray system including:
a tray section having a floor and one or more tray walls, the floor being configured to extend underneath one or more components of the liquid connector assembly; and
an engagement section coupled with the tray section and having one or more engagement portions configured to attach to the liquid manifold and position the tray section underneath the one or more components of the liquid connector assembly to capture the liquid.
